(19) United States
(12) Patent Application Publication
(10) Pub. No.: US 2002/0145177 A1
(43) Pub. Date: Oct. 10, 2002

(54) Semiconductor device

(76) Inventors: Hiroaki Takasu, Chiba-shi (JP); Jun Osanai, Chiba-shi (JP)

Correspondence Address: ADAMS & WILKS, 50 Broadway, 31st Floor, New York, NY, 10004, US

(21) Appl. No.: 10/096,397

(22) Filed: Mar. 12, 2002

(30) Foreign Application Priority Data
Apr. 9, 2001 (JP) 2001-110385

(51) Int. Cl. H01L 29/00

(52) U.S. Cl. 257/529

(57) ABSTRACT

A semiconductor device is provided: which is formed with an analog IC with high precision in which a complete depletion type high speed MOS transistor and a high pressure-resistance MOS transistor are mixedly mounted on an SOI substrate; which is resistant to ESD breakdown; in which a crack or peel is prevented in a dicing process; and in which trimming positioning precision is improved to enable cost-down. A laser trimming fuse element and a bleeder resistance are formed of a single crystal silicon device forming layer on the SOI substrate. The complete depletion type high speed MOS transistor and the high pressure-resistance MOS transistor are formed in the single crystal silicon device forming layer, and the thickness of the single crystal silicon device forming layer of the complete depletion type high speed MOS transistor region is made thin. An ESD protection element is formed on a silicon substrate in which the single crystal silicon device forming layer on the SOI substrate and a buried oxide film are removed. The single crystal silicon device forming layer and the buried oxide film are removed in a scribe region of a semiconductor integrated circuit.

### BACKGROUND OF THE INVENTION

1. Field of the Invention

The present invention relates to a semiconductor device having a semiconductor integrated circuit formed on an SOI substrate.

2. Description of the Related Art

Recently, a semiconductor integrated circuit formed on an SOI substrate is widely known. In particular,a high speed MOS transistor has superior characteristics by utilizing a complete depletion mode in comparison with a conventional MOS transistor formed on a silicon substrate.

Also, an N-type polycrystalline silicon thin film is widely known as a material for a gate electrode. Further, in order to attain high performance for obtaining a lower threshold voltage of a transistor, a so-called homopolar gate CMOS circuit, in which a P-type polycrystalline silicon thin film is used for a gate electrode of a P-type MOS transistor and an N-type polycrystalline silicon thin film is used for a gate electrode of an N-type MOS transistor, is used in some cases.

On the other hand, in an analog semiconductor integrated circuit device, there is known a laser trimming method for adjusting analog characteristics. For example, the method is disclosed in Japanese Patent Application Laid-open No. Hei 5-13670. An integrated circuit is two-dimensionally patterned on a semiconductor wafer, and thereafter, electrical characteristics of respective integrated circuits in a wafer state are measured. Next, a fuse element provided in a part of wiring is selected for adjusting analog characteristics, to thereby be cut by laser beam irradiation. With such a laser trimming method, the analog characteristics of the integrated circuit can be adjusted to desired characteristics by selectively cutting the fuse element. A positioning pattern is provided on a surface of the semiconductor wafer in order to irradiate a laser beam onto a predetermined fuse element. FIG. 2A is a plan view of a conventional positioning pattern, FIG. 2B is a sectional view of the conventional positioning pattern, and FIG. 2C is a diagram showing a variation in light reflection amount in the case where the positioning pattern is scanned with laser beam irradiation along a B-B′ line direction. In the conventional positioning pattern, a peripheral portion thereof corresponds to a first insulating film 102 made of a silicon oxide film and a second insulating film 104 made of a PSG film or the like which are formed on a silicon substrate 101, and a square aluminum film 105 is arranged inside the peripheral portion. When a laser beam is scanned along the B direction of FIG. 2A, a light reflection pattern as shown in FIG. 2C is obtained since the reflectivity of the aluminum film 105 is high. The positional relationship between the positioning pattern and the fuse element made of a polycrystalline silicon film of the integrated circuit has been determined at the time of design. Therefore, the positioning pattern is detected by laser beam irradiation, whereby the coordinates of a desired fuse element are calculated. Then, laser irradiation is conducted to the point, thereby making it possible to selectively trim the fuse element.

However, in the conventional semiconductor integrated circuit formed on an SOI substrate, particularly when a complete depletion mode is used, the thickness of a single crystal silicon device forming layer provided on the SOI substrate through a buried oxide film needs to be approximately 1000 Å or less. Thus, it has been difficult that a high pressure-resistance element or an ESD protection element for preventing ESD breakdown (electrostatic breakdown) is provided in a thin single crystal silicon device forming layer.

Further, in the conventional semiconductor integrated circuit formed on the SOI substrate, scribing is not considered, and there is the case where a defect such as a crack or a peel is caused in a dicing process for cutting out IC chips.

Further, the N-type polycrystalline silicon thin film is widely known as the material for a gate electrode. Due to the relationship between work functions of the gate electrode and single crystal silicon forming a channel region, particularly due to the characteristics on a leak current control of a P-type MOS transistor, or the like, it is difficult to shorten the gate length (what is called, L length) of the transistor. Therefore, there has been a problem in that it is difficult to obtain a large drain current. Regarding one of solutions to the problem, a so-called homopolar gate CMOS circuit, in which a P-type polycrystalline silicon thin film is used for a gate electrode of a P-type MOS transistor and an N-type polycrystalline silicon thin film is used for a gate electrode of an N-type MOS transistor, is used in some cases with the aim of attaining high performance for obtaining a lower threshold voltage of the transistor. However, there has been a problem in that the manufacturing process is complicated, and that cost of an IC chip rises.

On the other hand, it is known that, not only an IC formed on the SOI substrate, but also, in general, a fuse element is formed from a polycrystalline silicon film. However, in laser trimming, a fuse element and a positioning pattern are formed from different thin films, and thus, a precise positioning cannot be conducted. That is, in the case where the positioning pattern is detected with an aluminum pattern, thereby laser-trimming the polycrystalline silicon film that is the fuse element, as shown in FIG. 8, a laser irradiation region 32 is shifted with respect to a fuse element 31. Since energy distribution of the laser irradiation region 32 is Gaussian distribution, an energy intensity at the end portion of laser irradiation is low. Therefore, in a wafer process, there has been a problem in that a fuse element cannot be cut steadily if there is a large shift between patterning of the polycrystalline silicon film and patterning of the aluminum film. Note that reference numeral 33 denotes char of a base, and reference numeral 34 denotes a portion to be the remainder of a cut fuse.

Further, in an analog IC such as a voltage detector, a bleeder resistance consisting of a plurality of polycrystalline silicon resistors is used in many cases. However, it is difficult that the polycrystalline silicon resistors obtain the same resistance value due to an influence of grain, which has been a bottleneck for manufacturing an analog IC with high precision.

### SUMMARY OF THE INVENTION

The present invention has been made in view of the above, and an object of the present invention is therefore to provide a semiconductor device at a low cost and with high performance: which is formed with an analog IC with high precision in which a complete depletion type high speed MOS transistor and a high pressure-resistance MOS transistor are mixedly mounted on an SOI substrate; which is resistant to ESD breakdown; and in which a crack or peel is prevented in a dicing process.

Further, another object of the present invention is to improve positioning precision of trimming to thereby attain the effect of reducing a fuse element region in size and enable cost-down.

In order to solve the above objects, the present invention takes the following means.

(1) There is provided a semiconductor device including a semiconductor integrated circuit formed on an SOI substrate in which a laser trimming fuse element, a laser trimming positioning pattern, a complete depletion type high speed MOS transistor, a high pressure-resistance MOS transistor, an ESD protection element, and a plurality of resistors are formed.

(2) There is provided a semiconductor device according to (1), in which: the laser trimming positioning pattern is constituted of a high light reflectivity region and a low light reflectivity region; the high light reflectivity region is formed of a high light reflectivity film formed on a flat base; and the low light reflectivity region is formed of the high light reflectivity film, which is formed on a pattern having a lattice, stripe or dotted shape for causing light diffused reflection and which is comprised of the same thin film as the laser trimming fuse element.

(3) There is provided a semiconductor device according to (1), in which the laser trimming fuse element is formed of a single crystal silicon device forming layer on the SOI substrate.

(4) There is provided a semiconductor device according to (1), in which: the complete depletion type high speed MOS transistor and the high pressure-resistance MOS transistor are formed in the single crystal silicon device forming layer; the ESD protection element is formed on a silicon substrate in which the single crystal silicon device forming layer on the SOI substrate and a buried oxide film are removed; and the thickness of the single crystal silicon device forming layer of the region where the complete depletion type high speed MOS transistor is formed is thinner than the thickness of the single crystal silicon device forming layer of the region where the high pressure-resistance MOS transistor is formed.

(5) There is provided a semiconductor device according to (1), in which at least one of a gate electrode of the complete depletion type high speed MOS transistor including both an N-type MOS transistor and a P-type MOS transistor and a gate electrode of the high pressure-resistance MOS transistor including both an N-type MOS transistor and a P-type MOS transistor is formed of a P-type polycrystalline silicon thin film or a composite film of the P-type polycrystalline silicon thin film and a high melting point metal thin film.

(6) There is provided a semiconductor device according to (1), in which the bleeder resistance is formed of the single crystal silicon device forming layer.

(7) There is provided a semiconductor device according to (6), in which the thickness of the single crystal silicon device forming layer of the region where the bleeder resistance is formed is equal to the thickness of the single crystal silicon device forming layer of the region where the complete depletion type high speed MOS transistor is formed.

(8) There is provided a semiconductor device according to (1), in which a single crystal silicon device forming layer and a buried oxide film are removed in a scribe region of the semiconductor integrated circuit.

### BRIEF DESCRIPTION OF THE DRAWINGS

In the accompanying drawings:

FIG. 1 is a schematic sectional view of a semiconductor device according to the present invention;

FIGS. 2A to 2C are a plan view of a positioning pattern of a conventional semiconductor device, a sectional view of the positioning pattern of the conventional semiconductor device, and a diagram showing a light reflection amount along a B-B′ line of FIG. 2A, respectively;

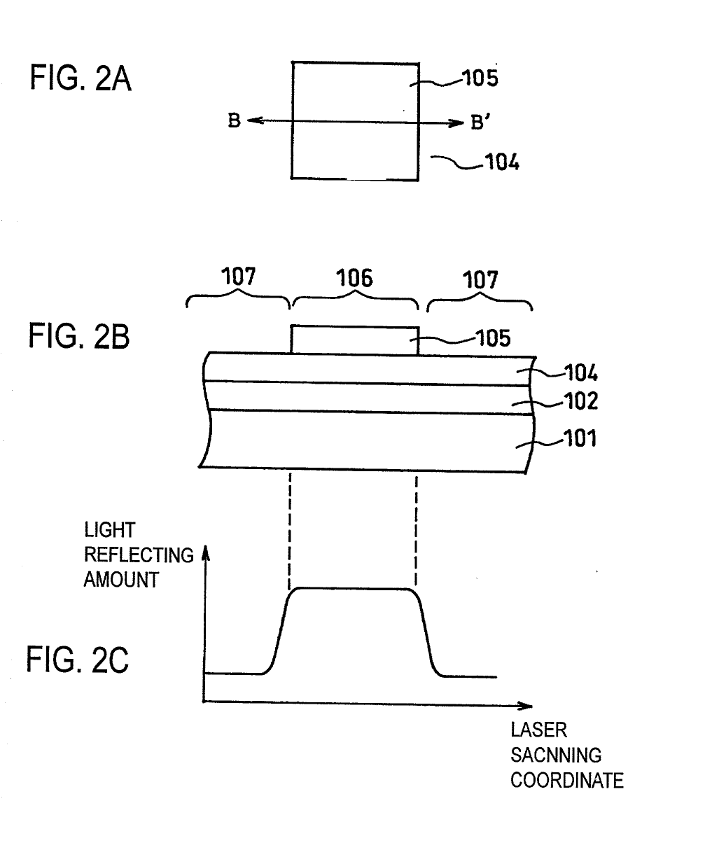

FIGS. 3A to 3C are a plan view of a positioning pattern of a semiconductor device in accordance with a first embodiment of the present invention, a sectional view of the positioning pattern of the semiconductor device in accordance with the first embodiment of the present invention, and a diagram showing a light reflection amount along an A-A′ line of FIG. 3A, respectively;

FIGS. 4A to 4C are a plan view of a positioning pattern of a semiconductor device in accordance with a second embodiment of the present invention, a sectional view of the positioning pattern of the semiconductor device in accordance with the second embodiment of the present invention, and a diagram showing a light reflection amount along a C-C′ line of FIG. 4A, respectively;

FIGS. 5A to 5C are a plan view of a positioning pattern of a semiconductor device in accordance with a third embodiment of the present invention, a sectional view of the positioning pattern of the semiconductor device in accordance with the third embodiment of the present invention, and a diagram showing a light reflection amount along a D-D′ line of FIG. 5A, respectively;

FIGS. 6A to 6C are a plan view of a positioning pattern of a semiconductor device in accordance with a fourth embodiment of the present invention, a sectional view of the positioning pattern of the semiconductor device in accordance with the fourth embodiment of the present invention, and a diagram showing a light reflection amount along an E-E′ line of FIG. 6A, respectively;

FIGS. 7A to 7C are a plan view of a positioning pattern of a semiconductor device in accordance with a fifth embodiment of the present invention, a sectional view of the positioning pattern of the semiconductor device in accordance with the fifth embodiment of the present invention, and a diagram showing a light reflection amount along an F-F′ line of FIG. 7A, respectively;

FIG. 8 is a plan view of a fuse element of the conventional semiconductor device;

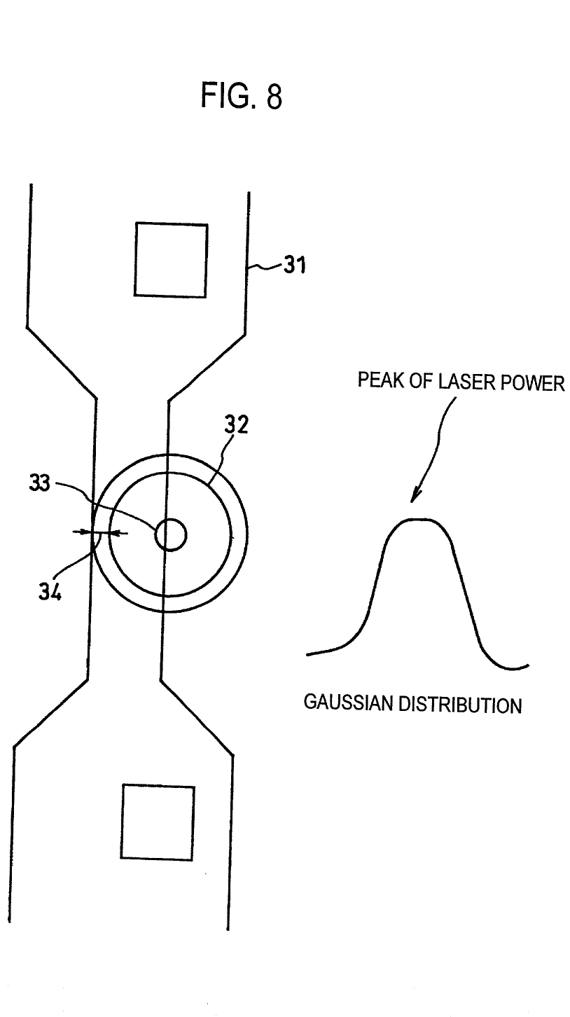

FIG. 9 is a plan view of a fuse element of the semiconductor device according to the present invention; and

FIG. 10 is a block diagram of the semiconductor device according to the present invention.

### DETAILED DESCRIPTION OF THE PREFERRED EMBODIMENTS

In a semiconductor integrated circuit formed on an SOI substrate, a laser trimming fuse element, a laser trimming positioning pattern, a complete depletion type high speed MOS transistor, a high pressure-resistance MOS transistor, an ESD protection element, and a bleeder resistance formed by a plurality of resistors are formed.

The laser trimming positioning pattern is constituted of a high light reflectivity region and a low light reflectivity region. The high light reflectivity region is formed of a high light reflectivity film formed on a flat base, and the low light reflectivity region is formed of the high light reflectivity film, which is formed on a pattern having a lattice, stripe or dotted shape for causing light diffused reflection and which is comprised of the same thin film as the laser trimming fuse element.

The laser trimming fuse element and the bleeder resistance are formed of a single crystal silicon device forming layer on the SOI substrate. Further, the complete depletion type high speed MOS transistor and a high pressure-resistance MOS transistor are formed in the single crystal silicon device forming layer, and the ESD protection element is formed on a silicon substrate in which the single crystal silicon device forming layer on the SOI substrate and a buried oxide film are removed. The thickness of the single crystal silicon device forming layer of the region where the complete depletion type high speed MOS transistor is formed is made thinner than the thickness of the single crystal silicon device forming layer of the region where the high pressure-resistance MOS transistor is formed.

At least one of a gate electrode of the complete depletion type high speed MOS transistor including both an N-type MOS transistor and a P-type MOS transistor and a gate electrode of the high pressure-resistance MOS transistor including both an N-type MOS transistor and a P-type MOS transistor is formed of a P-type polycrystalline silicon thin film or a composite film of the P-type polycrystalline silicon thin film and a high melting point metal thin film.

Further, the bleeder resistance is formed of the single crystal silicon device forming layer. Desirably, the thickness of the single crystal silicon device forming layer of the region where the bleeder resistance is formed is made equal to the thickness of the single crystal silicon device forming layer of the region where the complete depletion type high speed MOS transistor is formed.

Moreover, in a scribe region of the semiconductor integrated circuit, the single crystal silicon device forming layer and the buried oxide film are removed.

Thus, it is possible to provide a semiconductor device at a low cost and with high performance: which is formed with an analog IC with high precision in which the complete depletion type high speed MOS transistor and the high pressure-resistance MOS transistor are mixedly mounted; which is resistant to ESD breakdown; and in which a crack or peel in a dicing process is prevented.

Particularly, the laser trimming positioning pattern is constituted of the high light reflectivity region and the low light reflectivity region. The high light reflectivity region is formed of a high light reflectivity film formed on a flat base, and the low light reflectivity region is formed of the high light reflectivity film, which is formed on a pattern having a lattice, stripe or dotted shape for causing light diffused reflection and which is comprised of the same single crystal silicon device forming layer as the laser trimming fuse element. Therefore, the boundary of the high light reflectivity region and the low light reflectivity region, that is, the part where the light reflectivity changes steeply is defined by the pattern formed of the same single crystal silicon device forming layer as the laser trimming fuse element. Thus, precise laser trimming can be conducted without any influence of the shift in the wafer process.

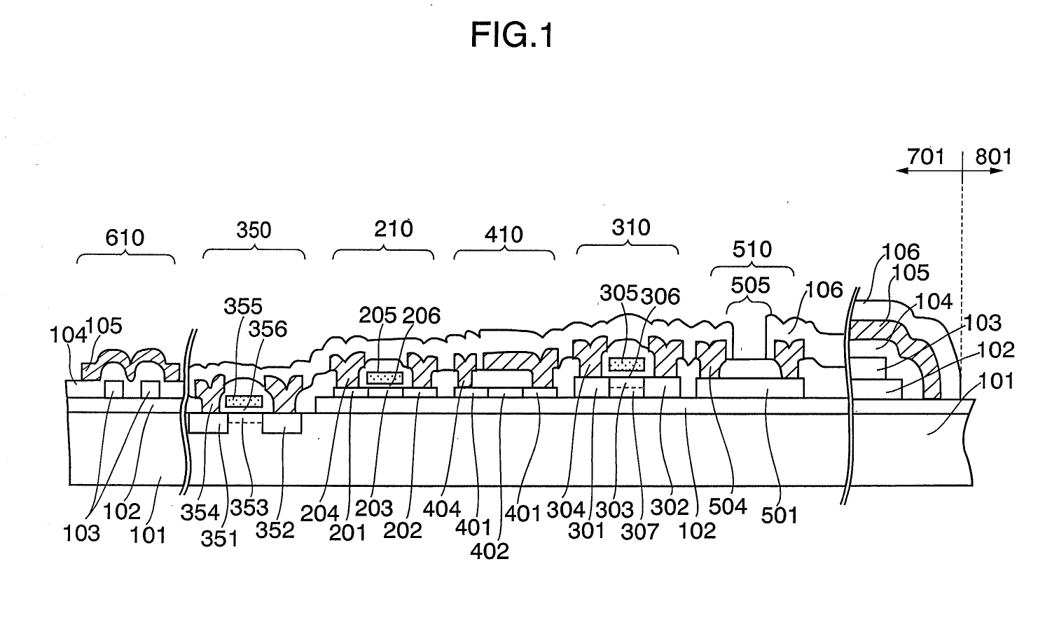

Hereinafter, embodiments of the present invention will be described with reference to the drawings. FIG. 1 is a schematic sectional view of a semiconductor device according to the present invention. Description will be made on respective regions in order with reference to FIG. 1.

First, a complete depletion type high speed MOS transistor region 201 is described.

In a single crystal silicon device forming layer 103 formed on a silicon substrate 101 through an buried oxide film 102, a source region 201, a drain region 202, and a channel region 203 are formed. Further, a gate electrode 205 is arranged above the channel region 203 through a gate oxide film 206, thereby forming a MOS transistor. Here, the thickness of the single crystal silicon device forming layer 103 is set to, for example, 500 Å so as to attain complete depletion. Further, an aluminum film 105 is connected to the source region 201 and the drain region 202 through contact holes 204 opened in an intermediate insulating film 104 formed of a BPSG film or the like. Then, a protection film 106 formed of a silicon nitride film or the like is formed as the uppermost layer on the high speed MOS transistor region 201.

Here, the potential of the channel region 203 may be made floating or fixed depending on the situation. Further, the source region 201 and the drain region 202 are desirably formed such that bases thereof contact the buried oxide film 102 with the purpose of reducing the capacity. However, it may be adopted that a depletion layer is formed with a depth to such an extent that it contacts the buried oxide film 102 at the time of application of a voltage and that the source region 201 and the drain region 202 are spaced from the buried oxide film 102.

Next, a high pressure-resistance MOS transistor region 310 is described.

In the single crystal silicon device forming layer 103 formed on the silicon substrate 101 through the buried oxide film 102, a source region 301, a drain region 302, a channel region 303, and a body region 307 are formed. Further, a gate electrode 305 is arranged above the channel region 303 through a gate oxide film 306, thereby forming a MOS transistor. Here, the thickness of the single crystal silicon device forming layer 103 is made thicker than the thickness of the single crystal silicon device forming layer 103 of the complete depletion type high speed MOS transistor region 201 described above, and is set to 5000 Å, for example. Further, the aluminum film 105 is connected to the source region 301 and the drain region 302 through contact holes 304 opened in the intermediate insulating film 104 formed of the BPSG film or the like. Then, the protection film 106 formed of the silicon nitride film or the like is formed as the uppermost layer on the high pressure-resistance MOS transistor region 301.

Here, differing from the above-described high speed MOS transistor region 201, the high pressure-resistance MOS transistor region 310 has a characteristic that the body region 307 is formed below the channel region 303.

The potential of the body region 307 is reliably fixed, whereby parasitic bipolar operation of the MOS transistor can be suppressed. Thus, operation with a high drain voltage is enabled. Further, in some cases, the thickness of the gate oxide film 306 of the high pressure-resistance MOS transistor region 301 may be set to be thicker than that of the gate oxide film 206 of the high speed MOS transistor region 201 if necessary.

Next, an ESD protection circuit region 350 will be explained.

A source region 351, a drain region 352, and a channel region 353 are formed on the silicon substrate 101, and a gate electrode 355 is arranged above the channel region 353 through a gate oxide film 356, thereby forming a MOS transistor. Further, the aluminum film 105 is connected to the source region 351 and the drain region 352 through contact holes 354 opened in the intermediate insulating film 104 made of the BPSG film or the like. Then, the protection film 106 formed of the silicon nitride film or the like is formed as the uppermost layer on the ESD protection circuit region 350 as in the case of the high speed MOS transistor region 201 and the like.

Here, differing from the high speed MOS transistor region 201 and the high pressure-resistance MOS transistor region 310, the ESD protection circuit region 350 has a characteristic that the single crystal silicon device forming layer 103 and the buried oxide film 102 are removed and that an element is directly formed on the silicon substrate 101. Thus, although particularly not shown in the figure, a high pressure-resistance MOS transistor suitable for a high operational voltage which has a DDD structure, a LOCOS-drain structure, or the like can be easily formed. Further, the gate oxide film 356 may be formed thicker than the gate oxide film 206 of the high speed MOS transistor region 210 or the gate oxide film 306 of the high pressure-resistance MOS transistor region 310. Moreover, although not particularly shown in the figure, the ESD protection circuit is formed on the silicon substrate 101, whereby an off-transistor or a diode having heat capacity and junction area, which has a sufficient resistance to the ESD, can be formed.

Only one complete depletion type high speed MOS transistor and only one high pressure-resistance MOS transistor are shown in FIG. 1 for simplicity. However, in actuality, the above transistors each has a CMOS structure composed of both an N-type MOS transistor and a P-type MOS transistor. At least one of the gate electrode 205 of the N-type MOS transistor and the P-type MOS transistor of the complete depletion type high speed MOS transistor and the gate electrode 305 of the N-type MOS transistor and the P-type MOS transistor of the high pressure-resistance MOS transistor is formed of a P-type polycrystalline silicon thin film or a composite film of the P-type polycrystalline silicon thin film and a high melting point metal thin film.

Described as follows is the reason for that the P-type polycrystalline silicon thin film or the composite film of the P-type polycrystalline silicon thin film and the high melting point metal thin film is used for at least one of the gate electrode of the complete depletion type high speed MOS transistor and the gate electrode of the high pressure-resistance MOS transistor.

The P-type polycrystalline silicon is used for the gate electrode in the P-type Mos transistor, whereby an E-type PMOS channel is a surface channel in accordance with the relationship of work functions between single crystal silicon forming the channel and the gate electrode. However, in the surface channel type PMOS, extreme deterioration of a subthreshold coefficient is not caused even if the threshold voltage is set to −0.5 V or more, for example, and low voltage operation and lower power consumption are both enabled.

On the other hand, in the N-type MOS transistor, an E type NMOS channel is a buried channel in accordance with the relationship of work functions between the gate electrode formed of the P-type polycrystalline silicon and the P-type single crystal silicon forming the channel. However, since arsenic having a small diffusion coefficient can be used as donor impurity for threshold control in case of setting a desired threshold value, the channel is an extremely shallow buried channel. Therefore, even if the threshold voltage is set to a small value, for example, 0.5 V or less, boron having a large diffusion coefficient and a large projection range for ion implantation has to be used as acceptor impurity for threshold control. Thus, deterioration of subthreshold and increase of a leak current can be remarkably suppressed in comparison with the E-type PMOS in which the N-type polycrystalline silicon that becomes a deep buried channel is used for the gate electrode.

From the above description, it will be understood that the CMOS according to the present invention in which the P-type polycrystalline silicon is used for the gate electrode is effective to low voltage operation and low power consumption in comparison with the conventional CMOS in which the N-type polycrystalline silicon is used for the gate electrode.

Further, a so-called homopolar gate CMOS technique is generally known regarding the low voltage operation and low power consumption. In the homopolar gate formation, in order to separately form a P-type gate electrode and an N-type gate electrode, at least two masking processes are additionally required in comparison with a general monopolar gate process. The standard number of masking processes for the monopolar gate CMOS is approximately ten. However, when the homopolar gate CMOS is formed, process cost increases by approximately 20%. Thus, it may be considered that the CMOS according to the present invention, in which the P-type polycrystalline silicon is used for the gate electrode, is effective from the total viewpoint of performance and cost of a semiconductor device.

In addition, it is generally difficult that the P-type polycrystalline silicon thin film is made to have low-resistance in comparison with the N-type polycrystalline silicon thin film. Thus, there is a problem in that a single film becomes a relatively high-resistant film. Therefore, it is desirable that the composite film of the P-type polycrystalline silicon thin film and the high melting point metal film is used to attain low-resistance in a circuit in which high-speed operation is considered to be very important.

Next, a bleeder resistance region 410 will be described.

In the single crystal silicon device forming layer 103 formed on the silicon substrate 101 through the buried oxide film 102, a pair of high concentration impurity regions 401 and a low concentration impurity region 402 sandwiched therebetween are formed, thereby forming a resistor. Although only one resistor is shown for simplicity here, a bleeder resistance is formed by a plurality of resistors in actuality.

Further, the aluminum film 105 is connected to the high concentration impurity regions 401 through contact holes 404 opened in the intermediate insulating film 104 formed of the BPSG film or the like. Here, the aluminum film 105 connected to one of the high concentration impurity regions 401 is arranged so as to cover the low concentration impurity region 402 that determines a resistance value of the resistor, and serves to attain stability of the resistance value.

This is for preventing variation in the resistance value of the resistor due to the potential difference between a conductor close to the resistor and the resistor itself. When all the resistors forming the bleeder resistance are manufactured in the same manner such that the potential of the aluminum film 105 above the resistor is not a power source potential or a ground potential but a potential at an end of the bleeder resistance, the potential difference between the aluminum film 105 positioned above the respective resistors and the resistors themselves is hardly caused. Thus, the resistors processed to have the same size exhibit the same resistance value. The bleeder resistance circuit is formed by using these resistors, whereby voltage division with high precision is enabled.

Further, in comparison with a conventional bleeder resistance formed from a polycrystalline silicon thin film, the resistor is formed by the single crystal silicon device forming layer 103 itself in the present invention. Thus, the influence of grain of the polycrystalline silicon thin film can be eliminated, thereby making it possible to obtain resistors with more uniformity. Therefore, the bleeder resistance circuit with higher precision can be formed.

Moreover, temperature characteristics and precision between adjacent resistors are improved by thinning the thickness of the bleeder resistor. Thus, the thickness of the single crystal silicon device forming layer 103 of the bleeder resistance region 410 is made equal to the thickness of the single crystal silicon device forming layer 103 of the high speed MOS transistor region 210 described above, whereby simplification of the manufacturing process and improvement of ability of the bleeder resistance can be achieved at the same time.

Furthermore, the case is described in which the resistor having a high resistance value, in which the low concentration impurity region 402 sandwiched between the pair of high concentration impurity regions 401 is provided, is formed. However, for the application in which a high resistance value is not needed, the whole resistor may be comprised of the high concentration impurity region 401.

The protection film 106 formed of the silicon nitride film or the like is formed as the uppermost layer on the bleeder resistance region 410.

Next, a fuse region 510 will be explained.

A single crystal silicon fuse 501 is formed in the single crystal silicon device forming layer 103 formed on the silicon substrate 101 through the buried oxide film 102.

The single crystal silicon fuse 501 is one having a high impurity concentration in order to have satisfactory conductivity and lower the resistance value as much as possible.

The aluminum film 105 is connected to both ends of the single crystal silicon fuse 501 through contact holes 504 opened in the intermediate insulating film 104 formed of the BPSG film or the like. In the protection film 106, which is formed of the silicon nitride film or the like, as the uppermost layer on the fuse region 510, a portion corresponding to a laser irradiation region 505 is removed. This is for preventing trouble about cutting of the single crystal silicon fuse 501 due to the fact that energy of the laser beam irradiated at the time of laser trimming is absorbed to the protection film 106.

Next, a laser trimming positioning pattern region 610 will be explained.

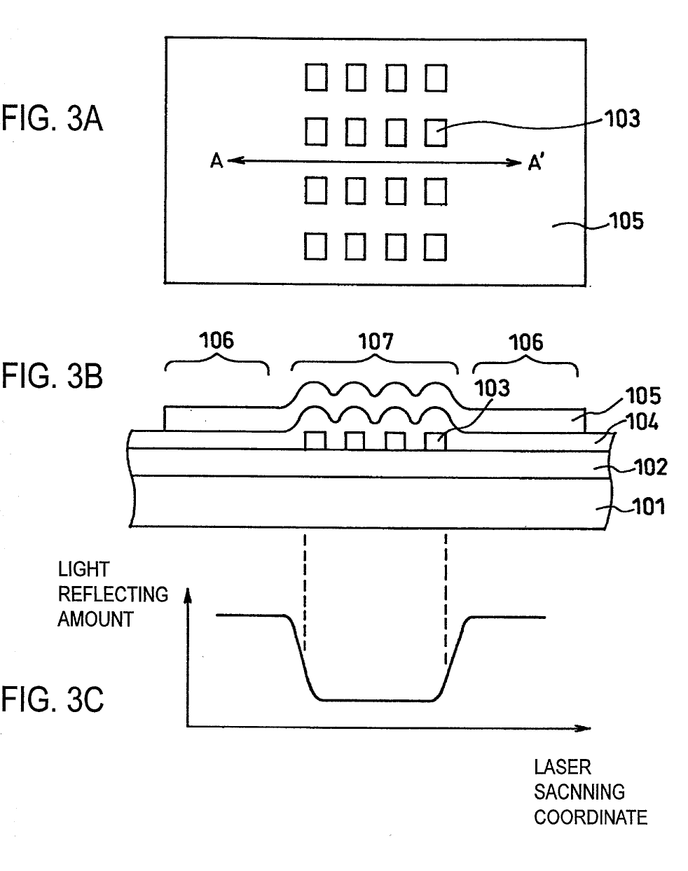

Here, the explanation will be made with reference to FIGS. 3A to 3C besides FIG. 1.

FIG. 3A is a plan view of a positioning pattern of a semiconductor device according to the present invention, FIG. 3B is a sectional view of the positioning pattern of the semiconductor device according to the present invention, and FIG. 3C is a diagram showing variation in light reflection amount in the case where the positioning pattern of the semiconductor device of the present invention is scanned with a laser beam. The light reflection amount is a value in the case where scanning is conducted along an A-A′ line direction of FIG. 3A.

The positioning pattern according to the present invention is constituted of high light reflectivity regions 106 and a low light reflectivity region 107 inside the regions as shown in FIG. 3B.

The structure of the positioning pattern of the present invention will be described with reference to FIGS. 3A and 3B.

The buried oxide film 102 is formed on the silicon substrate 101, and the single crystal silicon device forming layers 103 having a dotted shape are partially formed on the buried oxide film 102. The flat buried oxide film 102 is exposed in the region where the single crystal silicon device forming layers 103 are not formed, and the intermediate insulating film 104 formed of the BPSG film or the like is formed thereon. The aluminum film 105 is formed on the intermediate insulating film 104. The surface of the aluminum film 105, which is positioned above the region where the single crystal silicon device forming layers 103 having a dotted shape are formed, is uneven due to the influence of the pattern of the single crystal silicon device forming layers 103, and light irradiated to the portion is reflected diffusely. Therefore, this portion can be regarded as the low light reflectivity region 107. On the other hand, the surface of the aluminum film 105, which is positioned above the region where the single crystal silicon device forming layers 103 are not formed, is flat, and this portion can be regarded as the high light reflectivity region 106.

The light reflection amount in the case where scanning is conducted with a laser beam along the A-A′ line direction of FIG. 3A is large in the high light reflectivity regions 106 formed of the aluminum film 105 having a flat surface, and is small in the low light reflectivity region 107 formed of the aluminum film 105 having an uneven surface, as shown in FIG. 3C. In the examples of FIGS. 3A to 3C, the low light reflectivity region 107 is formed by utilizing the action of light diffused reflection. In order to cause the light diffused reflection, the dotted pattern is formed by the single crystal silicon device forming layers 103 formed of the same thin film as the single crystal silicon fuse 501. The light diffused reflection can be caused by the pattern having a lattice shape or a stripe shape other than the dotted shape, and the light reflection pattern as shown in FIG. 3C is obtained.

The intermediate insulating film 104 in FIG. 3B is not always needed, and thus, may be eliminated depending on the situation. Further, instead of the aluminum film 105, a metal material such as tungsten, chromium or gold may be used for the high light reflectivity film.

As described above, the boundary between the high light reflectivity region 106 and the low light reflectivity region 107 is determined by the pattern of the single crystal silicon device forming layers 103 formed of the same thin film as the single crystal silicon fuse 501. Thus, the boundary is released from the problem of the shift between the polycrystalline silicon forming the fuse element and the aluminum film forming the positioning pattern, which has been an object of the conventional positioning pattern.

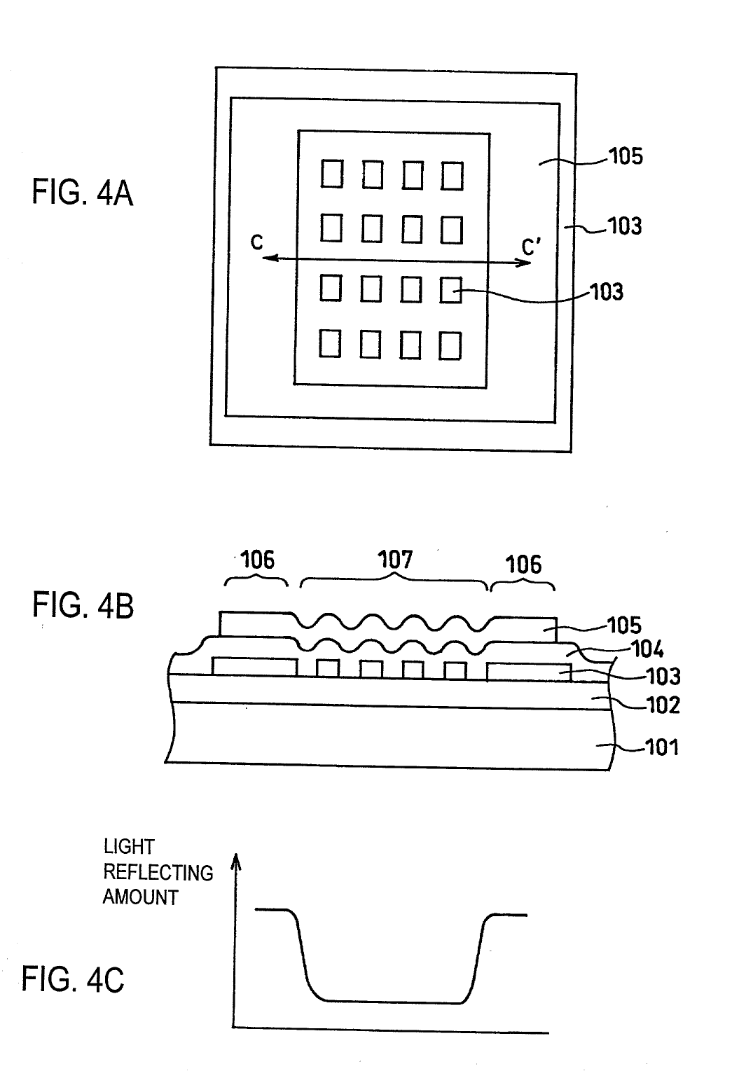

FIG. 4A is a plan view of a positioning pattern of a semiconductor device in accordance with a second embodiment of the present invention, FIG. 4B is a sectional view of the positioning pattern of the semiconductor device in accordance with the second embodiment of the present invention, and FIG. 4C is a diagram showing variation in light reflection amount in the case where the positioning pattern of the semiconductor device in accordance with the second embodiment of the present invention is scanned with a laser beam. The light reflection amount is the value in the case where scanning is conducted along a C-C′ line direction of FIG. 4A. The positioning pattern in accordance with the second embodiment of the present invention is constituted of the high light reflectivity regions 106 and the low light reflectivity region 107 inside the regions as in the first embodiment shown in FIGS. 3A to 3C.

The point different from the first embodiment is that the high light reflectivity regions 106 are formed of the flat aluminum film 105 positioned above the single crystal silicon device forming layer 103. If the high light reflectivity regions 106 are formed of the high light reflectivity film on a flat base, they can play their own parts. Thus, this structure can also be adopted. The same reference numerals as in FIGS. 3A to 3C are appended to in place of explanation for other parts.

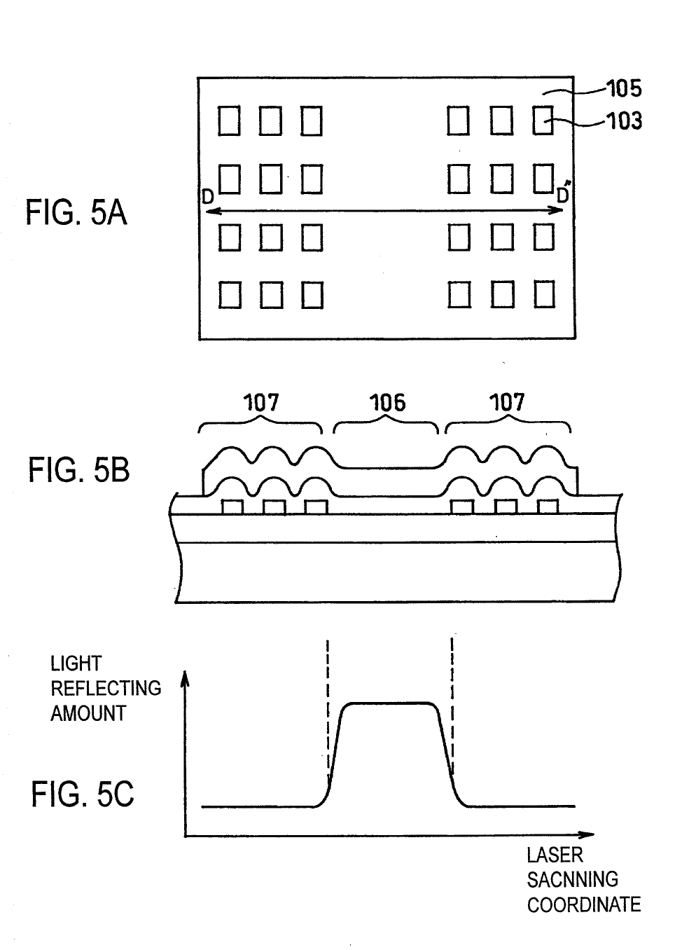

FIG. 5A is a plan view of a positioning pattern of a semiconductor device in accordance with a third embodiment of the present invention, FIG. 5B is a sectional view of the positioning pattern of the semiconductor device in accordance with the third embodiment of the present invention, and FIG. 5C is a diagram showing variation in light reflection amount in the case where the positioning pattern of the semiconductor device in accordance with the third embodiment of the present invention is scanned with a laser beam. The light reflection amount is the value in the case where scanning is conducted along a D-D′ line direction of FIG. 5A. The positioning pattern in accordance with the third embodiment of the present invention has the structure in which the low light reflectivity regions 107 and the high light reflectivity region 106 inside the regions are arranged. In the positioning pattern, one of the high light reflectivity region 106 and the low light reflectivity region 107 may be sandwiched between the other. The third embodiment shown in FIGS. 5A to 5C corresponds to the case where reverse arrangement of the first embodiment shown in FIGS. 3A to 3C is adopted. This indicates that such a structure may be taken. The same reference numerals as in FIGS. 3A to 3C are appended to in place of explanation for other parts.

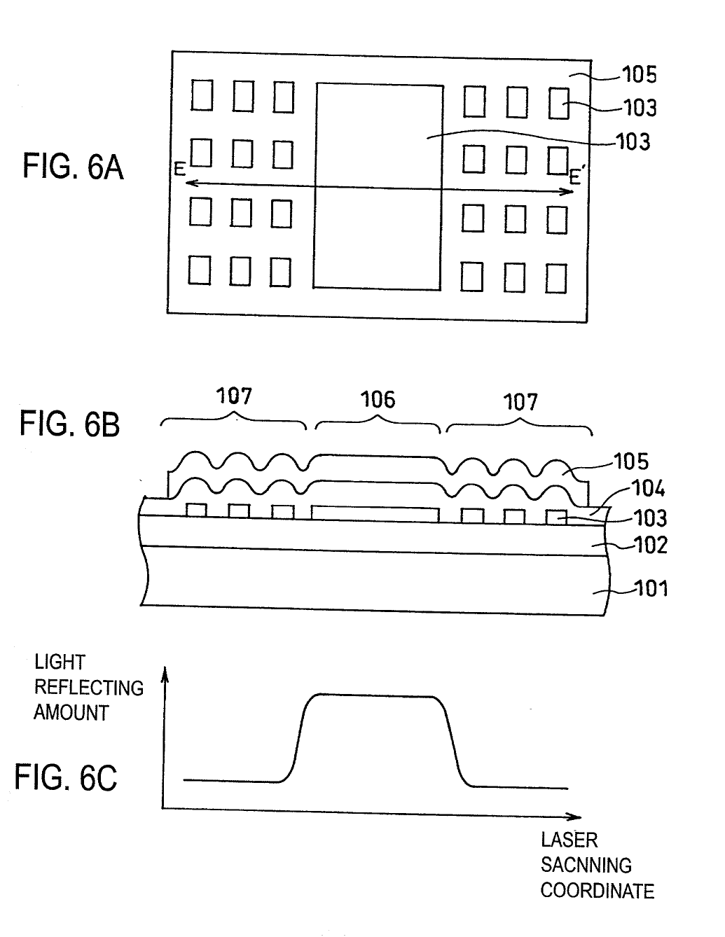

FIG. 6A is a plan view of a positioning pattern of a semiconductor device in accordance with a fourth embodiment of the present invention, FIG. 6B is a sectional view of the positioning pattern of the semiconductor device in accordance with the fourth embodiment of the present invention, and FIG. 6C is a diagram showing variation in light reflection amount in the case where the positioning pattern of the semiconductor device in accordance with the fourth embodiment of the present invention is scanned with a laser beam. The light reflection amount is the value in the case where scanning is conducted along an E-E′ line direction of FIG. 6A. The positioning pattern in accordance with the fourth embodiment of the present invention has the structure in which the low light reflectivity regions 107 and the high light reflectivity region 106 inside the regions are arranged.

Similarly to the description in the third embodiment, in the positioning pattern, one of the high light reflectivity region 106 and the low light reflectivity region 107 may be sandwiched between the other. The fourth embodiment shown in FIGS. 6A to 6C corresponds to the case where reverse arrangement of the second embodiment shown in FIGS. 4A to 4C is adopted. The same reference numerals as in FIGS. 3A to 3C are appended to in place of explanation for other parts.

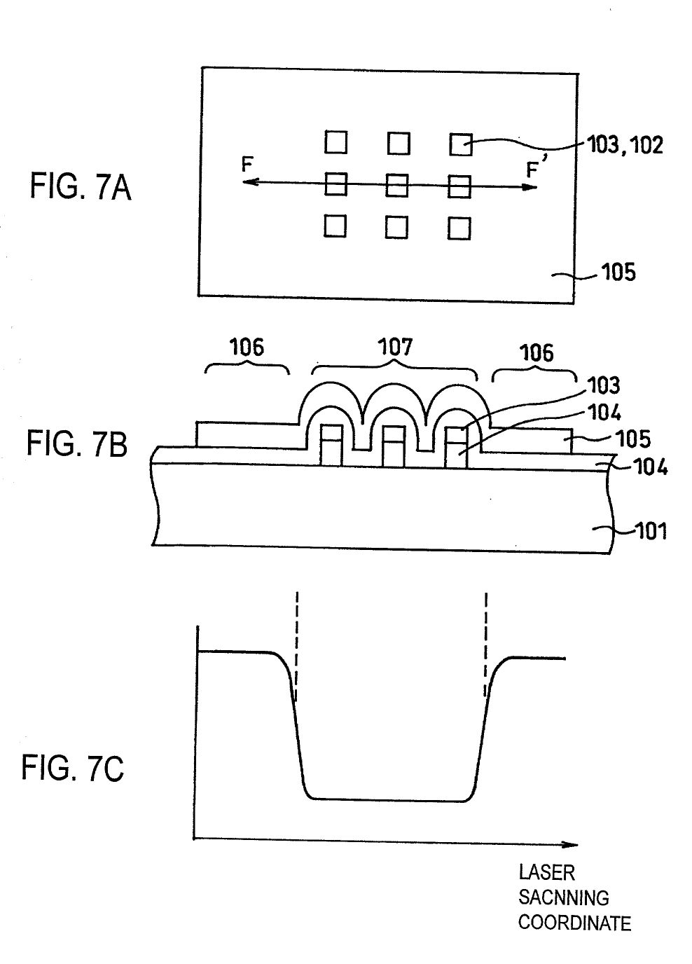

FIG. 7A is a plan view of a positioning pattern of a semiconductor device in accordance with a fifth embodiment of the present invention, FIG. 7B is a sectional view of the positioning pattern of the semiconductor device in accordance with the fifth embodiment of the present invention, and FIG. 7C is a diagram showing variation in light reflection amount in the case where the positioning pattern of the semiconductor device in accordance with the fifth embodiment of the present invention is scanned with a laser beam. The light reflection amount is the value in the case where scanning is conducted along an F-F′ line direction of FIG. 7A.

In the fifth embodiment of the present invention, the buried oxide film 102 and the single crystal silicon device forming layer 103 having a dotted shape are formed in alignment. The dot is formed by the composite film of the single crystal silicon device forming layer 103 and the buried oxide film 102. Thus, the height of the dot is higher, and unevenness of the surface of the aluminum film 105, which is positioned above the region where the single crystal silicon device forming layer 103 is formed, is also larger in comparison with the first embodiment. Therefore, the light irradiated to this position has a larger degree of diffused reflection in comparison with the first embodiment, which leads to further lowering of the light reflectivity.

The light reflection amount in the case where scanning is conducted with a laser beam along the F-F′ line direction of FIG. 7A is larger in the high light reflectivity regions 106 formed of the aluminum film 105 having a flat surface, and is smaller than the low light reflectivity region 107 formed of the aluminum film 105 having an uneven surface as shown in FIG. 7C.

Here, the dot is formed by the composite film of the single crystal silicon device forming layer 103 and the buried oxide film 102. Thus, the height of the dot can be higher, and the light reflectivity of the low light reflectivity region 107 can further be lowered. Therefore, the difference (contrast) of the light reflectivity between the low light reflectivity region 107 and the high light reflectivity region 106 can be made large. Accordingly, positioning with laser scanning is hardly disturbed by an external cause, and thus can be performed with more accuracy.

Note that the example, in which the dot is made higher on the basis of the first embodiment, is shown in the fifth embodiment. However, the height of the dot can be similarly made higher also in the second to fourth embodiments, which is effective. Further, the same effect can be obtained with not only the dotted shape but also a stripe shape or a lattice shape.

The same reference numerals as in FIGS. 3A to 3C are appended to in place of explanation for other parts.

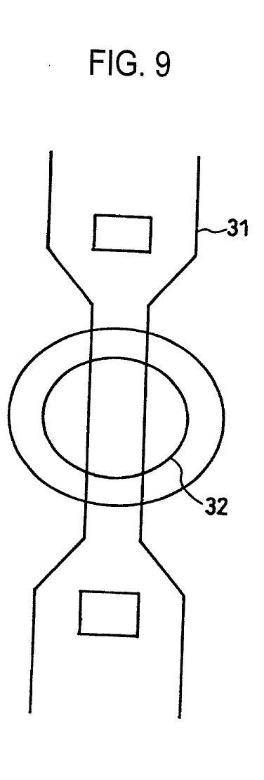

FIG. 9 is a plan view of a fuse element which has undergone laser trimming by using the positioning pattern of the semiconductor device according to the present invention. It becomes possible that the center of the fuse element 31 is irradiated with a laser spot 32.

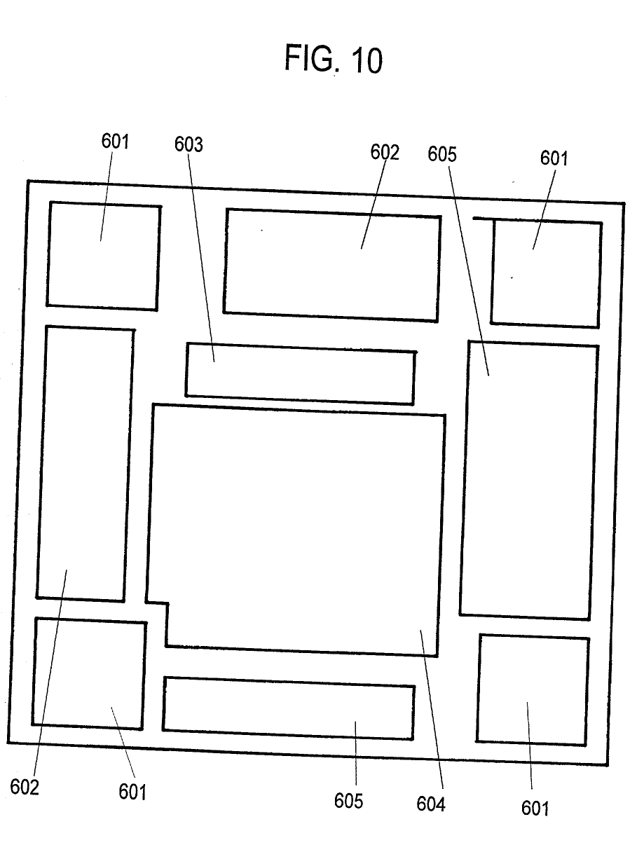

The semiconductor device according to the present invention is very suitable for a semiconductor integrated circuit comprised of semiconductor elements with large variation. For example, FIG. 10 is a block diagram of an IC for detecting a voltage and constructed by a MOS transistor having a high withstand voltage. The integrated circuit comprises four PADs 601, two comparators 602, a FUSE 603, poly R 604 and two output transistors 605. The MOSIC has larger variation in analog characteristics in comparison with a bipolar IC. Particularly, in case of a high pressure-resistance type, the variation in analog characteristics becomes larger increasingly since a gate insulating film is made thick. Therefore, in case of the analog MOSIC, a large fuse element region is required as shown in FIG. 10. Ten or more fuse elements are provided, thereby making it possible to obtain analog characteristics with reduced variation.

The fuse element can be made smaller by using the positioning pattern of the present invention. Further, it becomes possible that the fuse elements are arranged at two or more locations in different directions in plane.

The positioning pattern of the present invention can be implemented by being provided in any one of a scribe line, a semiconductor chip and a TEG chip. In the case where the positioning pattern is arranged in the scribe line or TEG chip, the effect is obtained for reducing the area of the semiconductor chip.

Further, the present invention is appropriate for analog MOSICs, and may also be applied to digital ICS. Also, the present invention is appropriate for realizing high density analog bipolar ICs with extremely small variation. In FIGS. 3A to 7C used for explaining the laser trimming positioning pattern region 610, the intermediate insulating film 104 is not always needed, and may be eliminated depending on the situation. Further, instead of the aluminum film 105, a metal material such as tungsten, chromium or gold may be used for the high light reflectivity film.

Next, a scribe region 801 will be explained.

In FIG. 1, a portion to be a cutting margin in the subsequent dicing process (process of cutting out an IC chip) is the scribe region 801. The scribe region 801 starts from the end of a semiconductor integrated circuit interior region 701. Here, the single crystal silicon device forming layer 103 and the buried oxide film 102 are removed in the scribe region 801. It is desirable that the intermediate insulating film 104, the aluminum film 105, the protection film 106 and the like are removed as shown in FIG. 1.

This is for preventing breakdown of an important IC chip or occurrence of malfunction due to propagation of a crack or peel to the semiconductor integrated circuit interior region 701 in the case where a force for causing damage such as the crack or peel is acted because of variation in the dicing process if the scribe region 801 that is the portion to be the cutting margin in the dicing process is connected to the semiconductor integrated circuit interior region 701 through the continuous single crystal silicon device forming layer 103.

Particularly, the IC formed on an SOI substrate has a structure in which the thin buried oxide film 102 and single crystal silicon device forming layer 103 are provided on the silicon substrate 101. Thus, a crack or peel of the buried oxide film 102 and the single crystal silicon device forming layer 103, which are upper layers, is easy to be caused, which requires attention.

It is an important point, for prevention of a crack or peel of an IC chip, that the continuous same film is not left between the scribe region 801 that is the cutting margin in the dicing process and the semiconductor integrated circuit interior region 701 to be the IC chip. Particularly regarding the IC formed on the SOI substrate, it is necessary that the single crystal silicon device forming layer 103 and the buried oxide film 102 are removed in the scribe region 801 as shown in FIG. 1. Also, the intermediate insulating film 104, the aluminum film 105, the protection film 106 and the like are desirably removed as shown in FIG. 1. Further, in the case where various marks and a test pattern needs to be formed in the scribe region 801, it may be adopted that the region where films concerned are removed is provided once between the scribe region 801 and the semiconductor integrated circuit interior region 701 and that the continuous same film is prevented from extending over the scribe region 801 and the semiconductor integrated circuit interior region 701.

In the semiconductor integrated circuit formed on the SOI substrate according to the present invention, the laser trimming fuse element, the laser trimming positioning pattern, the complete depletion type high speed MOS transistor, the high pressure-resistance MOS transistor, the ESD protection element, and the bleeder resistance formed by a plurality of resistors are formed.

The laser trimming positioning pattern is constituted of the high light reflectivity region and the low light reflectivity region. The high light reflectivity region is formed of the high light reflectivity film formed on the flat base, and the low light reflectivity region is formed of the high light reflectivity film, which is formed on the lattice, stripe, or dotted pattern for causing light diffused reflection and which is comprised of the same thin film as the laser trimming fuse element.

Further, the laser trimming fuse element and the bleeder resistance are formed of the single crystal silicon device forming layer on the SOI substrate.

The complete depletion type high speed MOS transistor and the high pressure-resistance MOS transistor are formed in the single crystal silicon device forming layer. The ESD protection element is formed on the silicon substrate in which the single crystal silicon device forming layer on the SOI substrate and the buried oxide film are removed. The thickness of the single crystal silicon device forming layer of the region where the complete depletion type high speed MOS transistor is formed is made thinner than the thickness of the single crystal silicon device forming layer of the region where the high pressure-resistance MOS transistor is formed.

Further, at least one of the gate electrode of the complete depletion type high speed MOS transistor including both the N-type MOS transistor and the P-type MOS transistor and the gate electrode of the high pressure-resistance MOS transistor including the N-type MOS transistor and the P-type MOS transistor is formed of the P-type polycrystalline silicon thin film or the composite film of the P-type polycrystalline silicon thin film and the high melting point metal thin film.

On the other hand, the scribe region in the semiconductor integrated circuit has the structure in which the single crystal silicon device forming layer and the buried oxide film are removed.

Thus, the semiconductor device: which is formed with an analog IC with high precision in which a complete depletion type high speed MOS transistor and a high pressure-resistance MOS transistor are mixedly mounted on an SOI substrate; which is resistant to ESD breakdown; and in which a crack or peel is prevented in a dicing process, can be provided at a low cost and with high performance.

In particular, the laser trimming positioning pattern is constituted of the high light reflectivity region and the low light reflectivity region. The high light reflectivity region is formed of the high light reflectivity film formed on the flat base, and the low light reflectivity region is formed of the high light reflectivity film, which is formed on the lattice, stripe, or dotted pattern for causing light diffused reflection and which is comprised of the same thin film as the laser trimming fuse element. Therefore, the boundary between the high light reflectivity region and the low light reflectivity region, that is the part where the light reflectivity changes steeply is defined by the pattern formed of the same single crystal silicon device forming layer as the laser trimming fuse element. Thus, precise laser trimming can be conducted without any influence of the shift in the wafer process.

What is claimed is:

1. A semiconductor device comprising a semiconductor integrated circuit formed on an SOI substrate in which a laser trimming fuse element, a laser trimming positioning pattern, a complete depletion type high speed MOS transistor, a partial depletion type high pressure-resistance MOS transistor, an ESD protection element, and a bleeder resistance formed by a plurality of resistors are formed.

2. A semiconductor device according to claim 1, wherein: the laser trimming positioning pattern is constituted of a high light reflectivity region and a low light reflectivity region; the high light reflectivity region is formed of a high light reflectivity film formed on a flat base; and the low light reflectivity region is formed of the high light reflectivity film, which is formed on a pattern having a lattice, stripe or dotted shape for causing light diffused reflection and which is comprised of the same thin film as the laser trimming fuse element.

3. A semiconductor device according to claim 1, wherein the laser trimming fuse element is formed of a single crystal silicon device forming layer on the SOI substrate.

4. A semiconductor device according to claim 1, wherein: the complete depletion type high speed MOS transistor and the high pressure-resistance MOS transistor are formed in the single crystal silicon device forming layer; the ESD protection element is formed on a silicon substrate in which the single crystal silicon device forming layer on the SOI substrate and a buried oxide film are removed; the thickness of the single crystal silicon device forming layer of the region where the complete depletion type high speed MOS transistor is formed is thinner than the thickness of the single crystal silicon device forming layer of the region where the high pressure-resistance MOS transistor is formed, and the complete depletion type high speed MOS transistor is operated in a complete depletion mode; and the thickness of the single crystal silicon device forming layer of the region where the high pressure-resistance MOS transistor is formed is sufficient to make a body region in a non-depletion state remain under a channel region of the high pressure-resistance MOS transistor.

5. A semiconductor device according to claim 1, wherein at least one of a gate electrode of the complete depletion type high speed MOS transistor including both an N-type MOS transistor and a P-type MOS transistor and a gate electrode of the high pressure-resistance MOS transistor including both an N-type MOS transistor and a P-type MOS transistor is formed of a P-type polycrystalline silicon thin film.

6. A semiconductor device according to claim 1, wherein at least one of a gate electrode of the complete depletion type high speed MOS transistor including both an N-type MOS transistor and a P-type MOS transistor and a gate electrode of the high pressure-resistance MOS transistor including both an N-type MOS transistor and a P-type MOS transistor is formed of a composite film of a P-type polycrystalline silicon thin film and a high melting point metal thin film.

7. A semiconductor device according to claim 1, wherein the bleeder resistance is formed of the single crystal silicon device forming layer.

8. A semiconductor device according to claim 7, wherein the thickness of the single crystal silicon device forming layer of the region where the bleeder resistance is formed is equal to the thickness of the single crystal silicon device forming layer of the region where the complete depletion type high speed MOS transistor is formed.

9. A semiconductor device according to claim 1, wherein a single crystal silicon device forming layer and a buried oxide film are removed in a scribe region of the semiconductor integrated circuit.
